(19) United States
(12) Patent Application Publication
(10) Pub. No.: US 2009/0074206 A1
(43) Pub. Date: Mar. 19, 2009

(54) METHOD OF ENHANCING SOUND FOR HEARING IMPAIRED INDIVIDUALS

(75) Inventors: KIPP BRADFORD, PAWTUCKET, RI (US); RALPH A. BECKMAN, PROVIDENCE, RI (US); JOHN F. MURPHY, III, NORTH SCITUATE, RI (US)

Correspondence Address: BARLOW, JOSEPHS & HOLMES, LTD., 101 DYER STREET, 5TH FLOOR, PROVIDENCE, RI, 02903, US

(73) Assignee: BIONICA CORPORATION, Providence, RI (US)

(21) Appl. No.: 11/854,693

(22) Filed: Sep. 13, 2007

(51) Int. Cl. H03G 5/00

(52) U.S. Cl. 381/103

(57) ABSTRACT

A portable assistive listening system for enhancing sound for hearing impaired individuals includes a fully functional hearing aid and a separate handheld digital signal processing (DSP) device. The focus of the present invention is directed to the handheld DSP device and a unique method of processing incoming audio signals. The DSP device includes a programmable digital signal processor, a UWB transceiver for communicating with the hearing aid and/or other wireless audio sources, an LCD display, and a user input device (keypad). The handheld device is user programmable to apply different sound enhancement algorithms for enhancing sound signals received from the hearing aid and/or other audio source. The handheld device is capable of receiving audio signals from multiple sources, and gives the user control over selection of incoming sound sources and selective enhancement of sound. Specifically, the invention focuses on a proprietary method of adjusting the master volume and equalization of each of the multiple incoming audio signals prior to mixing all of the enhanced signals for output. Applying a Master Volume and Equalization setting prior to mixing provides for a more evenly enhanced sound and better overall sound intelligibility, as well as reducing processing power drained from the system during use.

### BACKGROUND OF THE INVENTION

The instant invention relates to an assistive listening system including a hearing aid and a wireless, handheld, programmable digital signal processing device.

Programmable, “at-ear”, hearing aids are well-known in the art. When using the term “at-ear”, the Applicant intends to include all types of hearing aids that are located in the vicinity of the ear, such as Completely-in-the-Canal (CIC) hearing aids, Mini-Canal (MC) hearing aids, In-the-Canal (ITC) hearing aids, Half-Shell (HS) hearing aids, In-the-Ear (ITE) hearing aids, Behind-the-Ear (BTE) hearing aids, and Open-fit Mini-BTE hearing aids.

Prior art programmable hearing aids typically include a small, low-power digital audio processing device, or digital signal processor (DSP), which locally receives an audio input from an on-board microphone, processes the audio input and outputs the audio directly to the wearer through a small speaker. A DSP is specifically designed to perform the audio signal analysis and computation required to deliver the clearest sound to the user. This analysis and computation involves reshaping the audio signals using mathematical equations (algorithms). Because of the size of a typical at-ear hearing aid, audio processing power is limited and thus functionality is typically limited to just one audio processing algorithm (fixed set of calculations) and often a single hearing profile. Modifications to the hearing profile (personalized adjustments) typically require a trip to an audiologist to connect the hearing aid to a special interface to make adjustments. An audiologist can change the variables for the fixed set of calculations, but cannot change the calculations which are built into the hardware of the DSP. This process is akin to changing the equalizer settings where the gain of certain frequency ranges is increased or decreased depending on the wearer's hearing loss.

Programmable hearing aids that include the ability to process audio signals according to multiple hearing profiles are also well known in the art. In these devices, the audiologist is able to program multiple profiles into the hearing aid memory, and the user is able to select a particular hearing profile by manually actuating a switch on the hearing aid corresponding to the desired setting. However, the underlying processing algorithm (fixed mathematical calculations) remains the same.

Some of these multiple-profile hearing aids include a separate handheld programming device that can selectively push a programming profile to the hearing aid at the direction of the user. Alternatively, the handheld programming device samples ambient sound with an on-board microphone, analyzes the audio signal and then automatically sends (pushes) a programming signal to the earpiece to tell the earpiece how to process the audio signal (automatically sets the hearing profile). These separate handheld devices do have digital signal processing capabilities and do process ambient audio, but the processed audio is not transmitted back to the earpiece. Only a programming signal is transmitted back to the hearing aid. The actual signal processing is still completed in the hearing aid based on the hearing profile determined by the handheld device.

Assistive listening systems having a wireless earpiece and a separate handheld or base unit are also well known in the art. Some of these prior art systems provide for digital processing in the separate device, while others are simply wireless repeaters for taking in audio signals from a source and transmitting it to the earpiece. However, one aspect of these prior art systems is that the systems that provide for digital signal processing (DSP) in the handheld unit remove the audio signal processing capabilities from the earpiece. Where the DSP capabilities are preserved in the earpiece, the handheld or base unit is simply being used as a signal repeater.

### SUMMARY OF THE INVENTION

While the prior art programmable hearing aids and assistive listening devices have served the market for many years, demographics are rapidly changing such that many elderly people are now comfortable with electronic devices and computers, and society now generally embraces the concept of all people carrying and wearing listing devices, such as MP3 players. It is believed that there is an unmet need in the assistive listening industry for a versatile and powerful assistive listening system that combines the known benefits of at-ear hearing aids with the powerful programming and processing capabilities that are now available in advanced digital signal processors. By supplementing the audio processing functions of the hearing aid with a separate digital signal processing device, which can accommodate a larger audio processor, memory, input and output ports, the Applicant can significantly enhance the usability and overall functionality of hearing devices.

In one embodiment, an assistive listening system includes a hearing aid and a wireless, handheld, programmable digital signal processing device.

The hearing aid generally includes components of a programmable hearing aid, i.e. microphone, digital signal processor, speaker and power source. The hearing aid also includes an analog amplifier and a wireless ultra-wide band (UWB) transceiver for communicating with the separate handheld digital signal processor device.

The digital signal processing device generally includes a programmable digital signal processor, a UWB transceiver for communicating with the hearing aid, an LCD display, and a user input device (keypad). Other wireless transmission technologies are also contemplated.

The handheld device is user programmable to accept different processing algorithms for processing sound signals received from the hearing aid. The handheld device is also capable of receiving audio signals from multiple sources, and gives the user control over selection of incoming sources and selective processing of sound. In the context of being user programmable, the digital signal processing device includes a software platform that provides for the ability of the user to select, or plug-in, desired processing algorithms for application to selected incoming audio signals. The software platform that provides the ability to load and save different processing algorithms, to apply those processing algorithms to one or more incoming sound sources, and/or to apply multiple processing algorithms in series, if desired, and the method associated with processing of the incoming sound signals.

One aspect of the embodiments lies in a method of adjusting the master volume and equalization of each of the multiple incoming audio signals prior to mixing all of the processed signals for output. Prior art devices mixed separate audio sources first and then applied a volume and equalization to the mixed signals. However, the separate audio signals may have significantly different volume levels and an across the board volume adjustment at the end of the process may not enhance the intelligibility, but rather degrade its intelligibility. It is believed that applying a Master Volume and Equalization setting prior to mixing of the audio signals provides for a more evenly enhanced sound and better overall sound intelligibility, as well as reducing processing power drained from the system during use.

More specifically, an embodiment of the invention is directed to a method of enhancing sound for the hearing impaired comprising receiving at a first input a first digital audio signal generated from a first audio source, receiving at a second input a second digital audio signal generated from a second audio source, adjusting a master volume and equalization of each of the first and second audio signals, mixing the adjusted first and second audio signals, and outputting the mixed first and second audio signals.

Accordingly, among the embodiments of the instant invention are: an assistive listening system including an at-ear hearing aid and a separate handheld digital signal processing device that supplements the functional signal processing of the hearing aid; a handheld digital signal processing device that can accept sound signal from a plurality of different sources; a handheld digital signal processing device that is wireless; a wireless handheld DSP device that is user programmable to apply different processing algorithms for processing sound signals received from the hearing aid or other audio source; a method of processing sounds for the hearing impaired comprising receiving at a first input a first digital audio signal generated from a first audio source, receiving at a second input a second digital audio signal generated from a second audio source, adjusting a master volume and equalization of each of the first and second audio signals, mixing the adjusted first and second audio signals, and outputting the mixed first and second audio signals.

Other objects, features and advantages of the invention shall become apparent as the description thereof proceeds when considered in connection with the accompanying illustrative drawings.

### DESCRIPTION OF THE DRAWINGS

In the drawings which illustrate the best mode presently contemplated for carrying out the present invention:

FIG. 1 is a pictorial representation of a user wearing a pair of hearing aids and using the wireless, handheld digital signal processing (DSP) device according to an embodiment of the invention;

FIG. 2 is a schematic diagram of a embodiment of the system including one hearing aid and the handheld DSP device and wireless communication therebetween;

FIG. 2A is a flow chart depicting a operating scheme for the single hearing aid system as shown in FIG. 2;

FIG. 2B is a schematic diagram of a second embodiment of the system including a pair of hearing aids, and the handheld DSP device;

FIG. 2C is a flow chart depicting a operating scheme for the dual hearing aid system as shown in FIG. 2B;

FIG. 3 is a pictorial representation of a wireless, handheld DSP device constructed in accordance with an embodiment of the invention;

FIG. 4 is a pictorial representation of a wireless phone adapter constructed in accordance with an embodiment of the invention;

FIG. 5 is a pictorial representation of a wireless audio adapter constructed in accordance with an embodiment of the invention;

FIG. 6A is a pictorial representation of a wireless microphone constructed in accordance with an embodiment of the invention;

FIG. 6B is a pictorial side view of the wireless microphone;

FIG. 7 is a pictorial representation of a AM/FM broadcast receiver constructed in accordance with an embodiment of the invention;

FIG. 8 is a pictorial representation of a Bluetooth™ enabled device which is capable of communicating with the wireless, handheld DSP;

FIG. 9A is a pictorial representation of a wireless smoke alarm adapter constructed in accordance with an en invention;

FIG. 9B is a pictorial representation of the wireless handheld DSP device depicting a graphical representation of fire;

FIG. 10A is a pictorial representation of a wireless door bell adapter constructed in accordance with an embodiment of the invention

FIG. 10B is a pictorial representation of the wireless handheld DSP device depicting a graphical representation of a door bell;

FIG. 11 is a pictorial representation of the wireless handheld DSP device depicting a graphical representation of a cell phone;

FIG. 12 is a pictorial representation of a conventional pair of stereo headphones;

FIG. 13 is a pictorial representation of a conventional pair of stereo earbuds;

FIG. 14 is a pictorial representation of a conventional wireless headset;

FIG. 15 is a schematic diagram of the wireless, handheld DSP device constructed in accordance with an embodiment of the invention;

FIG. 16 is a schematic flow chart of the individual signal processing paths for each incoming audio stream handled by the wireless, handheld DSP device;

FIGS. 17A and 18B are schematic flow charts of a signal processing path for an incoming audio stream and showing the ability to selectively plug-in filter algorithms and enhancement algorithms;

FIG. 18 is a schematic flow chart of one implementation of comparative signal processing for parallel incoming audio streams; and

FIG. 19 is a schematic flow chart of a second implementation of comparative signal processing for parallel incoming audio streams.

### DESCRIPTION OF THE EMBODIMENTS

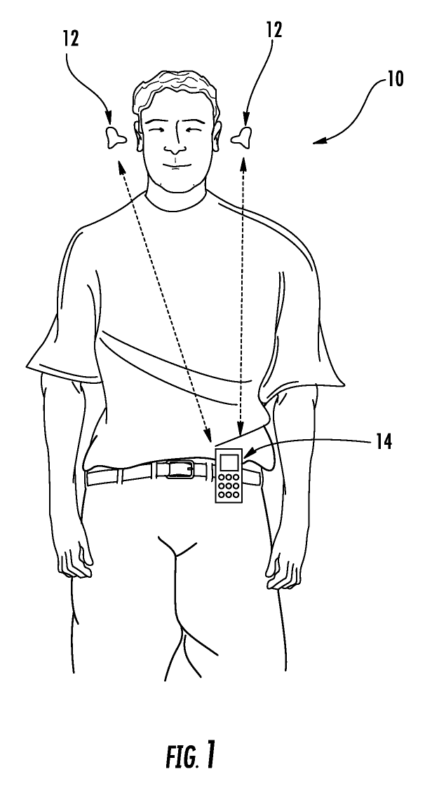

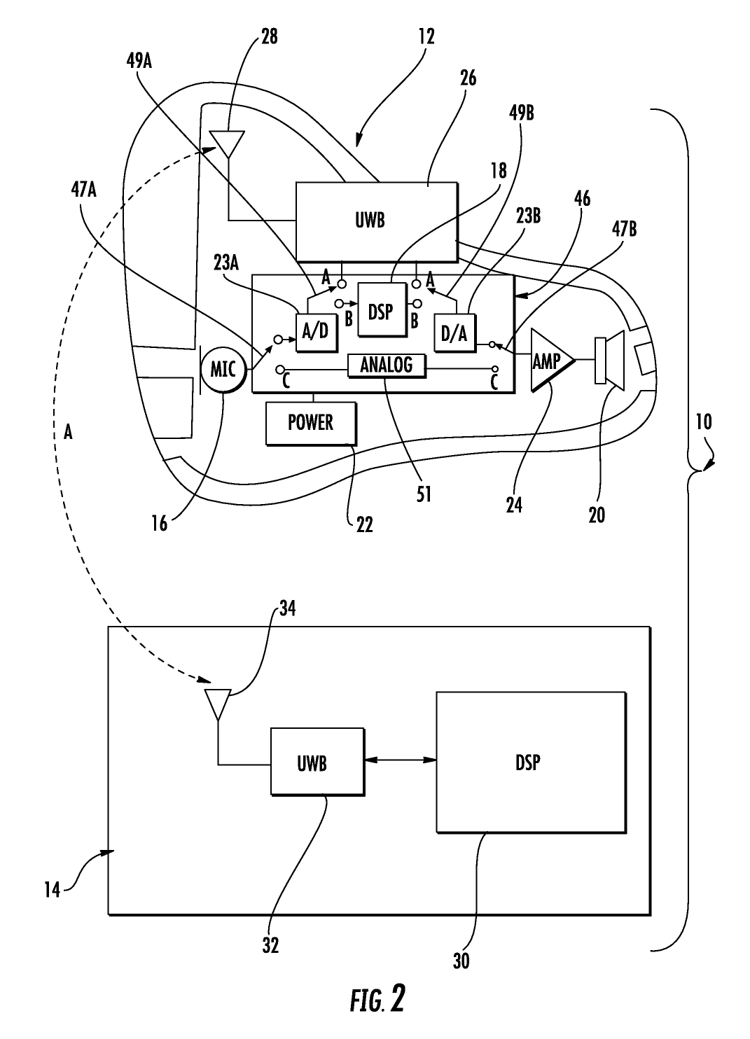

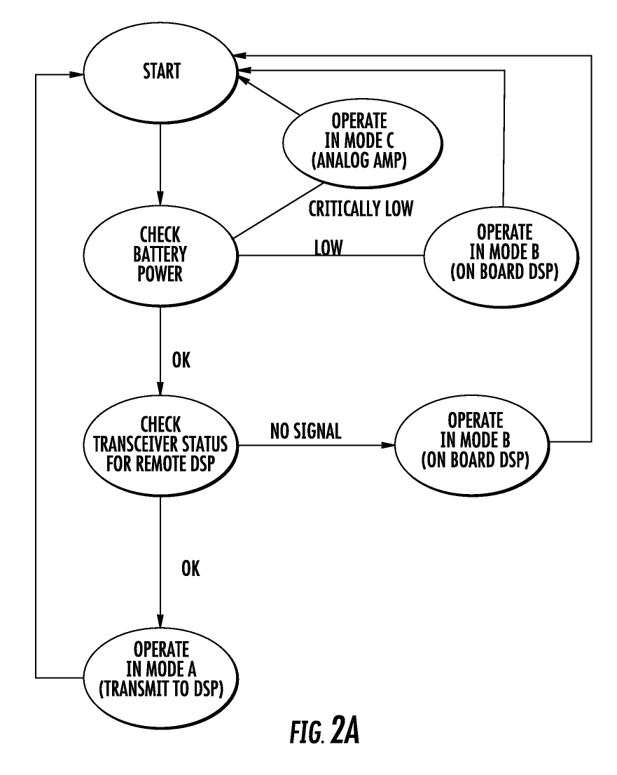

Referring now to the drawings, the assistive listening system of the present invention is illustrated and generally indicated at 10 in FIGS. 1 and 2. As will hereinafter be more fully described, the instant invention provides an assistive listening system 10 including a functional hearing aid generally indicated at 12 and a wireless, handheld, programmable digital signal processing (DSP) device generally indicated at 14.

The user depicted in FIG. 1 is shown to be using two hearing aid devices 12. It is common for the hearing impaired to use two hearing aids 12, one in each ear, as many hearing impaired individual have hearing loss in both ears. The use of two hearing aids 12 provides for better recognition of sound directionality, which is important in distinguishing and understanding sound. The depiction of the user in the drawing figures is not intended to limit the invention to a dual hearing aid system, and the following description will proceed from here forward substantially with respect to a system including only a single hearing aid 12. However, it is to be understood that the embodiments contemplate and provide for the use of either two hearing aids 12 or just a single hearing aid 12, it being understood that in a dual hearing aid system, both of the hearing aids 12 include the same hardware and functions. It should also be understood that the hearing aids 12 can be designed and implemented as any type of at-ear hearing aid.

Turning to FIG. 2, the hearing aid 12 generally includes components of a programmable hearing aid, i.e. a microphone 16, a digital signal processor 18, a speaker 20 and a power source 22. In the context of converting analog signal data from the microphone 16 to digital signal data for compatibility with the DSP 18 and vice versa for the speaker 20, the hearing aid 12 also includes an analog to digital converter (A/D) 23A and a digital to analog converter (D/A) 23B. Basic construction and operation of the programmable hearing aid 12 is known in the art and will not be described further.

In accordance with the invention, the hearing aid 12 also includes an analog amplifier 24 and a wireless Ultra-Wide Band (UWB) transceiver 26 and antenna 28 for communicating with the separate handheld digital signal processor device 14.

The Applicant has chosen Ultra-Wide Band (UWB) wireless communication as the preferred wireless transmission technology for transmitting and receiving data between the hearing aid and the handheld device. UWB is known for its fast transfer speeds and ability to handle large amounts of data. While the Applicant has selected UWB as the preferred wireless transmission technology, it is to be understood that other wireless technologies, such as Infra Red, WiFi, Bluetooth® (Bluetooth is a registered trademark of Bluetooth Sig, Inc), etc. are also suitable for accomplishing the same purpose (although at lower data rates and greater latency).

Referring to FIGS. 2, 3 and 15, the handheld digital signal processing (DSP) device 14 generally includes a programmable digital signal processor (DSP) 30, a UWB transceiver 32 and antenna 34 for communicating with the hearing aid 12 (and other UWB input devices), an LCD display 36, a user input device (keypad or touch-screen) 38, and a rechargeable battery power system generally indicated at 40.

The programmable DSP 30 is preferably a high-power audio processing device, such as Analog Devices®, Blackfin® BF-538 DSP, although other similar devices would also be suitable for use in connection with the invention (Analog Devices® and Blackfin® are trademarks or registered trademarks of Analog Devices Corp.).

The UWB transceiver 32 is similar to the UWB transceiver 26 in the hearing aid and is capable of wireless communication with the UWB transceiver 26 in the hearing aid.

The LCD screen 36 is a standard component that is well known in the industry and will not be described in further detail.

The user input device 38 is preferably defined as a keypad input. However, the Applicant also contemplates the use of a touch-screen input (not shown), as well as other mechanical and electrical inputs, scroll wheels, and other touch-based input devices. Where the input device 38 is a touch screen, the LCD and input device are combined into a single hardware unit. Touch-screen LCD devices are well known in the art, and will not be described in further detail.

The rechargeable battery system 40 includes a rechargeable battery 42, such as a conventional high capacity, lithium ion battery, and a power management circuit 44 to control battery charging and power distribution to the various components of the handheld DSP device 14.

In operation of the basic system 10, the hearing aid(s) 12 can independently operate without the handheld DSP device 14. The hearing aid 12 includes its own microphone 16, its own DSP 18 that can receive and process audio according to prior art processing methods, and its own speaker 20 for outputting audio directly to the wearer's ear.

An aspect of the present invention is a control and switching system 46 on-board the hearing aid 12 that monitors the wireless connection status of the handheld DSP device 14 and the power status of the hearing aid 12 and selectively routes the incoming audio from the hearing aid microphone 16 responsive to the status. When the hearing aid 12 is fully charged, and the handheld DSP device 14 is in communication range, the default operation is for the hearing aid 12 to route incoming audio from the on-board microphone wirelessly through the handheld DSP device 14 for processing (See FIGS. 2 and 2A—Mode A). More specifically, referring to FIG. 2, in Mode A, switches 47A and 47B are respectively set to route the incoming audio from the microphone to the A/D converter 23A and from the D/A converter 23B to the amplifier while the switches 49A and 49B are respectively set to deliver the signal from the A/D converter 23A to the UWB transceiver 16 and from the UWB transceiver 16 to the D/A converter 23B. The handheld DSP device 14 has a larger, more powerful DSP 30 and bigger power source 42 that can provide superior audio processing over longer periods of time. In addition, because of the user interface, and programmable software system, which will be discussed below, the user can select different processing schemes on the fly and selectively apply those processing schemes to the incoming audio.

When the control system 46 senses that the handheld DSP device 14 is not available, i.e. either out of range or low battery, the hearing aid control system 46 automatically defaults to the DSP 18 on-board the hearing aid 12 so that the hearing aid 12 functions as a conventional hearing aid (FIGS. 2 and 2A—Mode B). More specifically, referring to FIG. 2, in Mode B, switches 47A and 47B are respectively set to route the incoming audio from the microphone to the A/D converter 23A and from the D/A converter 23B to the amplifier while the switches 49A and 49B are respectively set to deliver the signal from the A/D converter 23A to the DSP 18 and from the DSP 18 to the D/A converter 23B.

When the control system 46 senses that the hearing aid 12 power is low, regardless of wireless status of the handheld DSP 14, it will automatically default to the on-board DSP 18 to conserve power that is normally consumed by the wireless transceiver 26 (FIGS. 2 and 2A—Mode B).

The hearing aid control system 46 will further automatically switch to a conventional analog amplifier mode when the hearing aid power is critically low (FIGS. 2 and 2A—Mode C). More specifically, referring to FIG. 2, in Mode C, switches 47A and 47B are respectively set to route the incoming audio from the microphone to an analog processor 51 and from the analog processor 51 to the amplifier. The set positions of switches 49A and 49B are not relevant to Mode C.

It is noted that switches 47A, 47B, 49A, 49B can be physical analog switches or software flags which determine where the signal is sourced from and sent to. It is also contemplated that the embodiment may further be implemented without an analog processing layer (Mode C).

Accordingly, it can be seen that the hearing aid control system 46 is effective for controlling the routing of audio signals received by the on-board microphone 16, and is further effective for automatically controlling battery management to extend the battery life and function of the hearing aid 12 to the benefit of the wearer.

Referring to FIG. 2B, there is illustrated another embodiment of the invention, wherein the system 10 includes two hearing aids 12. In this embodiment, it is preferable that the two hearing aids 12 also have the ability to wirelessly communicate with each other (See Communication Path A1). In this regard, when there are two hearing aids 12, and the control systems 46 in each hearing aid 12 detect that the handheld device 14 is not available, the control systems 46 can default to a binaural DSP mode where the two hearing aids 12 communicate and collectively process incoming audio signals according to a binaural processing scheme. (FIGS. 2B and 2C—Mode A1).

Further, an aspect of the binaural processing scheme in the present invention is that the control systems 46 can collectively perform load balancing where processing is first done in one hearing aid 12 and the other hearing aid 12 is in a low power transceiver mode, and then after a set period of time, the devices 12 swap modes in order to balance battery drain in each of the hearing aids (See FIG. 2C). In this regard, once the hearing aid 12 is operating in Mode A1, the control system 46 starts a load timing loop (time running) which loops until the set balance time expires, at which time, the devices 12 will swap modes.

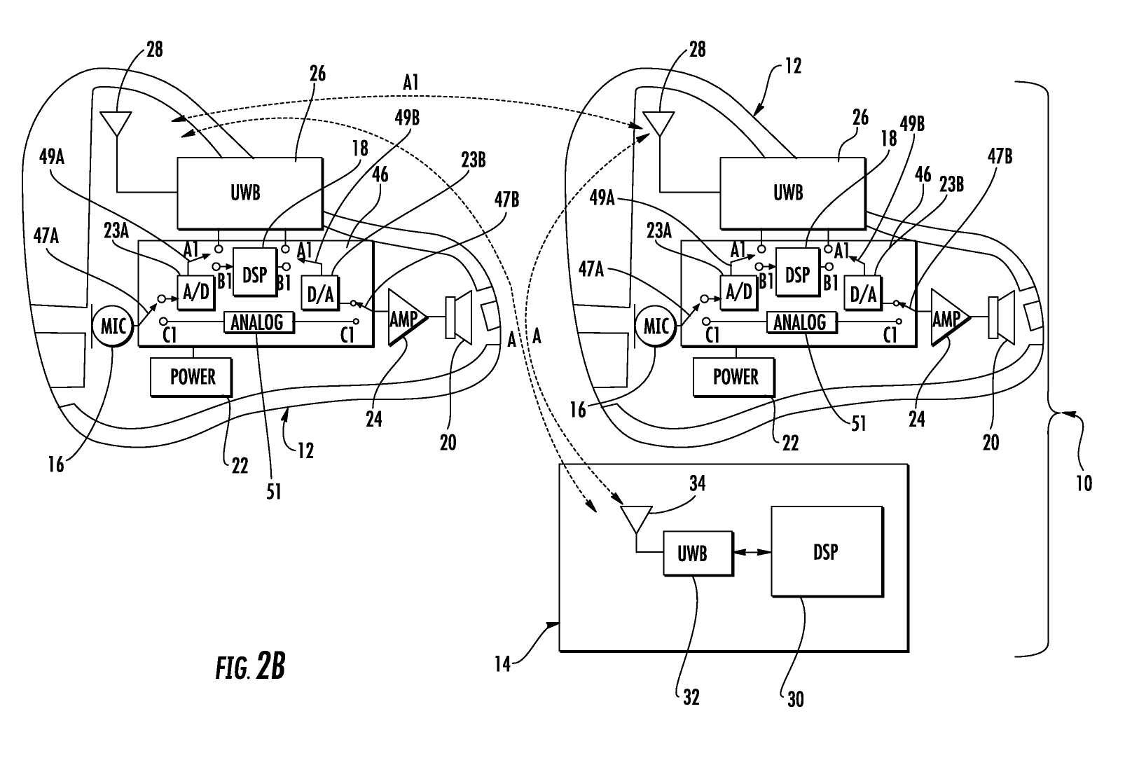

Yet another aspect of the invention is the ability of the handheld DSP device 14 to receive audio signals from other external sources. Turning to FIGS. 3-11 and 15, it can be seen the handheld DSP device 14 is capable of receiving audio signals from multiple incoming sources. In this regard, the handheld DSP device 14 includes a plurality of wired inputs, namely a stereo input jack generally indicated at 48, as well as an on-board microphone array including left, center and right microphone inputs generally indicated at 50, 52, and 54 respectively. Alternatively, the system 14 could be provided with physical input jacks to receive external wired microphones. The stereo input jack 48 includes a stereo jack connector 56, an input surge protector 58, and an analog to digital (A/D) converter 60, and is useful for receiving a direct audio signal from a personal audio device such as an MP3 player (not shown), or CD player (not shown). The left, center and right microphone inputs 50, 52, 54 each respectively include microphones 62, 64, 66 and an A/D converter 68, 70 and can be used to receive direct sound input from the surrounding environment (note the right and center microphones 64,66 share the same A/D converter 70).

The DSP device 14 further includes a T-coil sensor 72 for receiving signals from conventional telephones and American's with Disabilities Act (ADA) mandated T-coil loops in public buildings, or other facilities, which utilize T-coil loops to assist the hearing impaired. The T-coil sensor 72 shares the A/D converter 68 with the left microphone input 50.

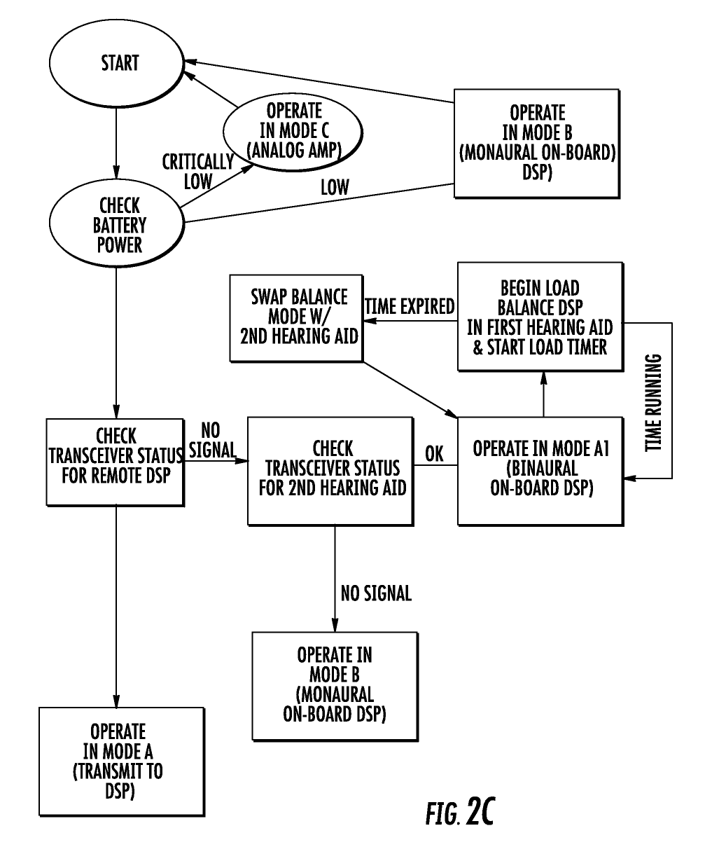

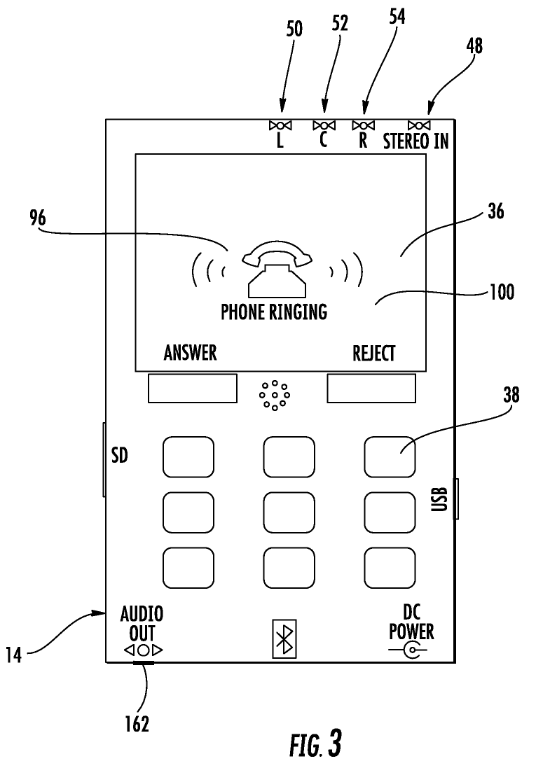

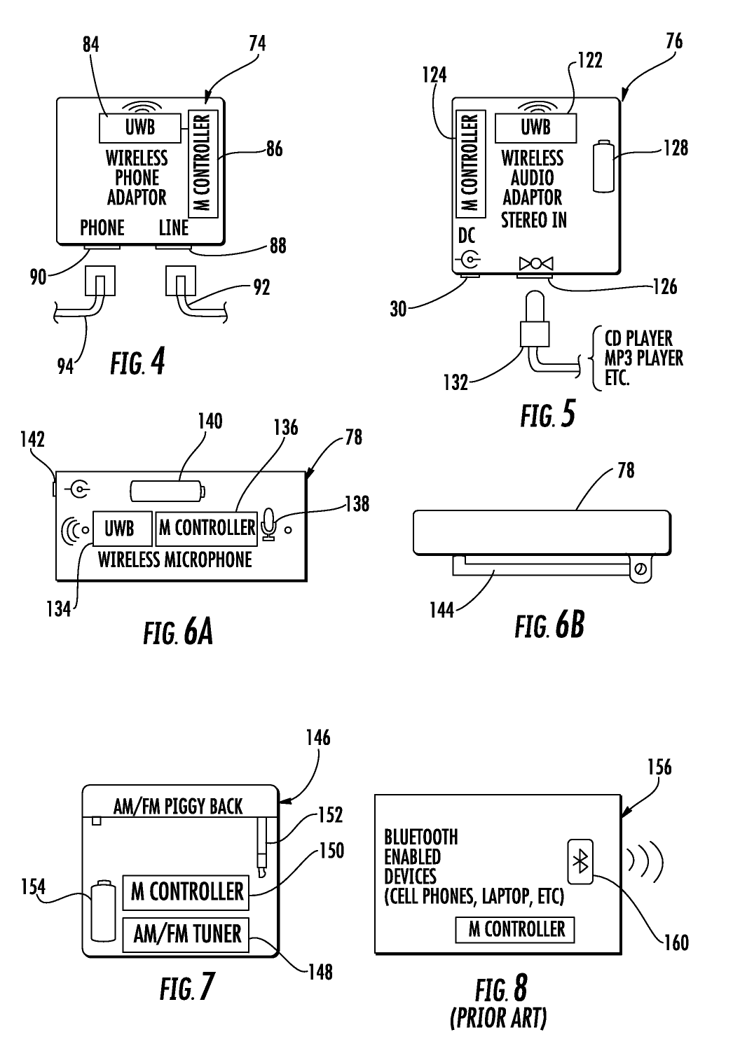

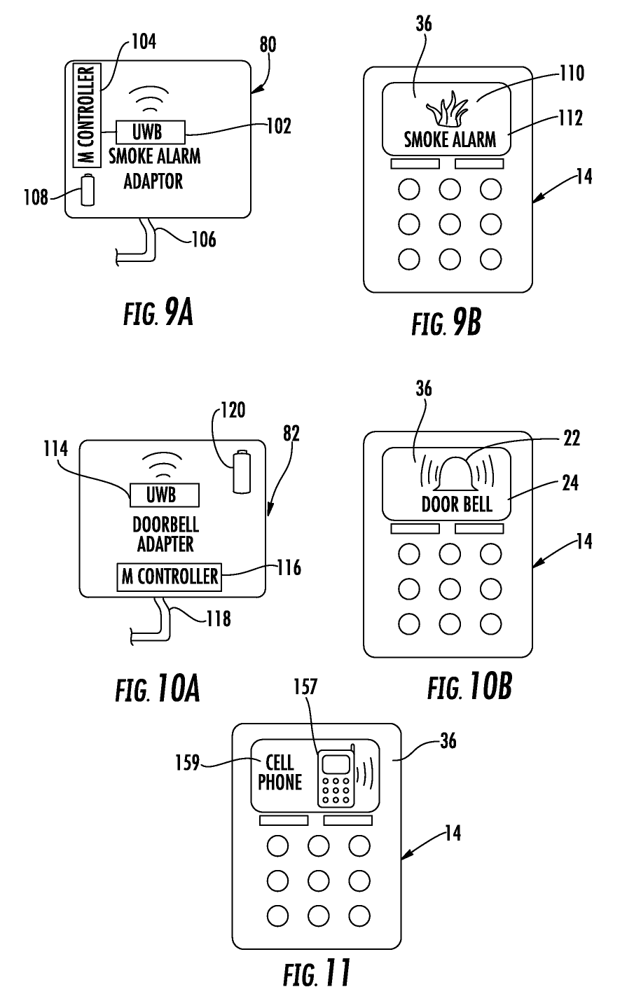

In addition to the UWB transceiver 32 being used for communicating with the hearing aid 12, the UWB transceiver 32 is also capable of receiving incoming wireless audio signals from a plurality of different wireless audio sources. In this regard, the system 10 is configured to include a UWB wireless telephone adapter generally indicated at 74 (FIG. 4), a UWB wireless audio adapter generally indicated at 76 (FIG. 5), at least one UWB wireless microphone generally indicated at 78 (FIG. 6A, 6B), a UWB wireless smoke alarm adapter generally indicated at 80 (FIG. 9A), and a UWB wireless door bell adapter generally indicated at 82 (FIG. 10A). The UWB transceiver 32 on-board the handheld DSP device 14 is capable of receiving multiple incoming signals from the various UWB devices 74, 76, 78, 80, 82 and the DSP on-board the handheld DSP device 14 is capable of multiplexing and de-multiplexing the multiple incoming signals, distinguishing one signal from the others, as well as processing the signals separately from the other incoming signals.

We now turn to a category of devices we refer to as “intermittent” audio sources. By “intermittent”, we simply mean that sound emanating from the source is not constant, i.e. a telephone ringing as opposed to sound emanating from a television, or that the user may not be attendant to the sound source and may thus not immediately recognize the sound. Referring to FIG. 4, the UWB wireless telephone adapter 74 includes a UWB transceiver 84, a microcontroller 86 (shown as M CONTROLLER in the drawings), and pass-through jacks 88, 90 connected to the microcontroller 86 for receiving the Line-in 92 and Phone line 94. The UWB telephone adapter 74 is powered by the existing voltage in the telephone line 92. The on-board microcontroller 86 is configured to intercept the incoming telephone call, wirelessly transmit a signal to the DSP device 14 to alert the user that there is an incoming call, and if accepted, to transmit the audio signal from the telephone directly to the DSP device 14 for processing and subsequent transmission from the handheld DSP device 14 to the hearing aid 12. The handheld DSP 14 is programmable to recognize each connected audio source, and in this regard, displays to the user on the LCD 36, a graphical representation 96 of a telephone to visually identify to the user the source of the signal (See FIG. 3). Recognition of each of the wireless sources can be accomplished by a pairing function similar to known Bluetooth® pairing functions where the wireless device 74, etc., transmits identification information to the handheld DSP device 14. It is known that it is easier to distinguish sounds when the source is known. For sounds that are “intermittent”, such as the telephone, a smoke alarm or a door bell, a visual cue as to the source of the sound makes the sound more recognizable to the user. The handheld DSP device 14 also preferably energizes a backlight 98 (FIG. 15) of the LCD display 36 as a further visual cue, and even further displays a text message 100 (FIG. 3) to the user, i.e. “telephone ringing”.

Similar to the concept of the wireless telephone adapter, FIGS. 9A and 9B, and 10A and 10B illustrate the wireless smoke alarm adapter 80 and the wireless doorbell adapter 82.

The wireless smoke alarm adapter 80 preferably includes a UWB transceiver 102, a microcontroller 104, and wired input 106 for series connection with a wired smoke alarm system (not shown). The UWB smoke alarm adapter 80 is preferably powered by the existing voltage in the wired smoke alarm line 106 and is configured to monitor the incoming signal voltage and wirelessly transmit an alarm signal to the DSP device 14 to alert the user that the smoke alarm is sounding. Wireless battery powered units (battery 108) are also contemplated. As indicated above, the handheld DSP device 14 is programmable to recognize each connected audio source, and in this regard, displays to the user on the LCD 36, a graphical representation 110 of a fire (or a smoke alarm) to visually identify to the user the source of the signal, as well as energizes the LCD backlight 98, and displays a text message 112 such as “SMOKE ALARM” or “FIRE”.

The wireless doorbell adapter 82 preferably includes a UWB transceiver 114, a microcontroller 116, and a wired input 118 for series connection with a wired doorbell system. The UWB doorbell adapter 82 is preferably powered by the existing voltage in the wired doorbell line and is configured to monitor the incoming signal voltage and wirelessly transmit a signal to the DSP device 14 to alert the user that the doorbell is ringing. Wireless battery powered units (battery 120) are also contemplated. As indicated above, the handheld DSP device 14 is programmable to recognize each connected audio source, and in this regard, displays to the user on the LCD 36, a graphical representation of a door bell to visually identify to the user the source of the signal as well as energizes the LCD backlight 98 and displays a text message such as “DOOR BELL”.

We now turn back to “constant” incoming audio sources and situations where the user is attendant to the source of the incoming sound. Referring to FIG. 5, the UWB wireless audio adapter 76 includes a UWB transceiver 122, a microcontroller 124 and a stereo input jack 126 for receiving an incoming stereo audio signal. The UWB wireless audio adapter 76 is preferably powered by its own battery power source 128 (rechargeable or non-rechargeable), but alternately can be power by a DC power source 130. The UWB wireless audio adapter 76 is configured to receive an incoming stereo audio signal from any stereo audio source 132 (MP3 player, CD player, Radio, Television, etc.), and wirelessly transmit the stereo audio signal to the DSP device 14 for processing and subsequent transmission from the handheld DSP device 14 to the hearing aid 12.

Turning to FIGS. 6A and 6B, the UWB wireless microphone 78 includes a UWB transceiver 134, a microcontroller 136, and a microphone 138 for collecting a local sound source. The UWB wireless microphone 78 is preferably powered by its own battery power source 140 (rechargeable or non-rechargeable), but alternately can be power by a DC power source 142. The wireless microphones 78 can be used for a plurality of different purposes; however, the most common use is for assistance in hearing conversation from another person. The UWB wireless microphone 78 collects local ambient sound and wirelessly transmits an audio signal to the DSP device 14 for processing and subsequent transmission from the handheld DSP device 14 to the hearing aid 12. As indicated above, the wireless microphone 78 is ideally suited for assistance in hearing another person during conversation. In this regard, the wireless microphone 78 includes a convenient spring clip 144 (FIG. 6B), which allows the microphone to be clipped to a person's collar or shirt, near the face so that the wearer's voice will be more easily collected and transmitted. Although only one microphone 78 is illustrated, the system 10 would preferably include multiple wireless microphones 78 for use by multiple persons associated with the user of the system 10. For example, the user may be having dinner with several persons in a crowded restaurant. The user could distribute several wireless microphones 78 to the persons at the table, pair the microphones 78 with the handheld DSP device 14 and thereby would be able to effectively hear each of the persons seated at the table.

Although the primary use of the wireless microphone 78 is intended for personal conversation, it is possible to use the microphone 78 in any situation where the user wants to listen to a localized sound. For example, if the user were a guest at someone's home, and wanted to watch television, the user could simply place the wireless microphone 78 adjacent to the television speaker in order to better hear the television without the need for the more specialized wireless audio adapter. Similarly, if the user were making a pot of coffee and were awaiting the ready signal, the user could place the microphone 78 next to the coffee maker and then go about other morning activities while awaiting the coffee to be ready. The wireless microphones 78 thus allow the user significant freedom of movement that hearing persons often take for granted.

Turning to FIG. 7, there is shown a piggyback AM/FM broadcast receiver 146, which can be plugged into the stereo audio in jack 48 on the handheld DSP device 14. This device 146 includes a conventional AM/FM broadcast tuner 148 and a microcontroller 150, which cooperate to tune in broadcast radio signals to be outputted directly through a local stereo jack 152 into stereo input jack 48 on the handheld DSP device. The AM/FM device 146 is preferably powered by its own battery source 154. This adapter 146 conveniently permits the handheld DSP device 14 to receive radio broadcast signals and transmit them to the wearer.

It should be noted that the handheld DSP device 14 can also recognize the wireless audio sources from the wireless audio adapter 76, wireless telephone adapter 74, and wireless microphone 78 and can display a visual cue to identify the input source.

It can be appreciated that the above-noted wireless input devices 74, 76, 78, 80, 82, 146 are all configured to function with the handheld DSP device 14 of the present invention. However, there are many existing wireless devices that can also be advantageously utilized with the present invention. For example, there are a multitude of Bluetooth® enabled devices 156 (FIG. 8) that can be linked with the handheld DSP device 14 for both input and output. In order for the DSP device 14 to communicate with existing Bluetooth® devices 156, the handheld DSP device 14 further includes a Bluetooth® transceiver 158 (FIG. 15) in communication with the DSP 30. With respect to audio input signals, both cell phones and laptops 156 (FIG. 8) typically include Bluetooth® transceivers 160 and thus can be paired with the handheld DSP device 14. The handheld DSP device 14 is preferably configured to recognize pairing with Bluetooth® enabled cell phones 156 such that the user can channel a cell phone call through the handheld DSP device 14. Referring briefly to FIG. 11, the handheld DSP device 14 is programmable to recognize each connected audio source, and in this regard, displays to the user on the LCD 36, a graphical representation of a cell phone 157 to visually identify to the user the source of the signal as well as energizes the LCD backlight 98 and displays a text message such as “CELL PHONE” 159. Likewise, the handheld DSP device 14 is preferably configured to recognize pairing with Bluetooth® enabled computers (also 156) to receive audio input from MP3 files or CD players on the computer, as well as to upload or download data to or from the computer.

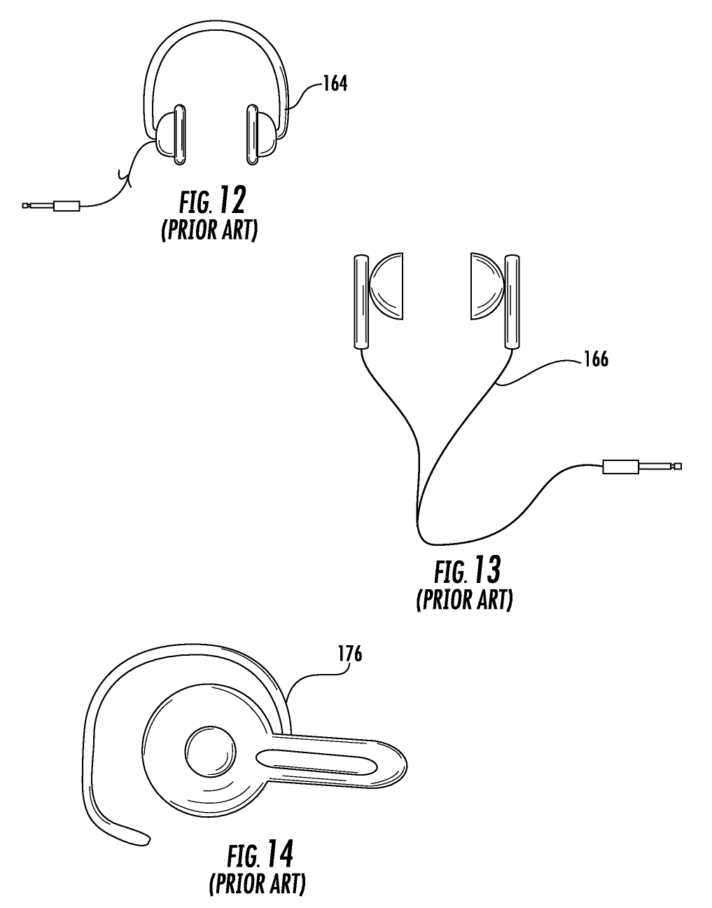

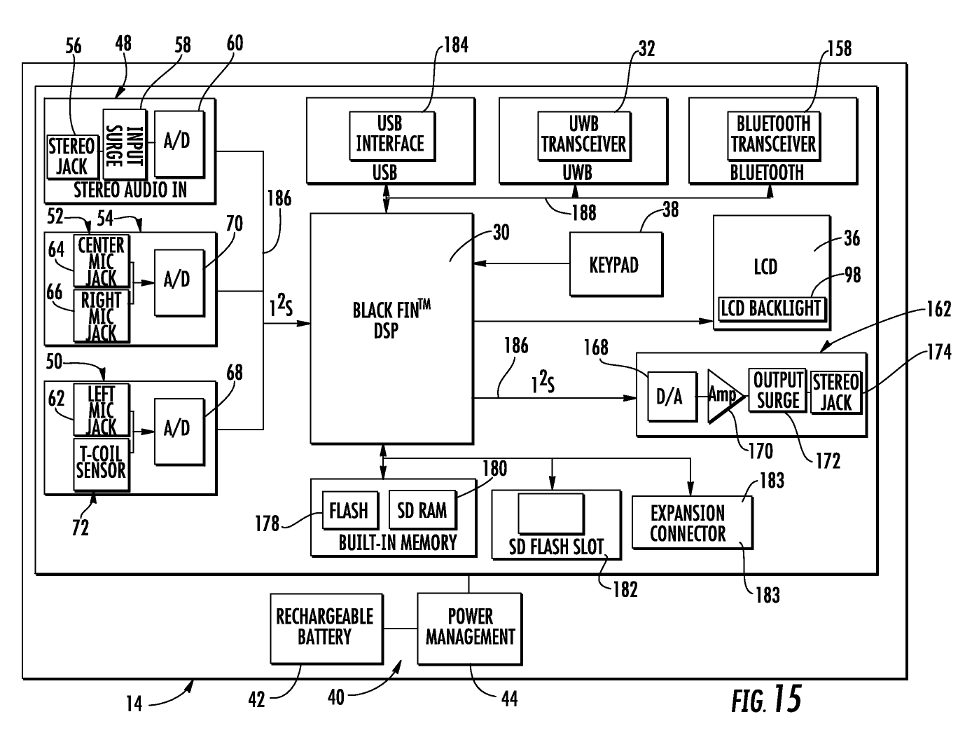

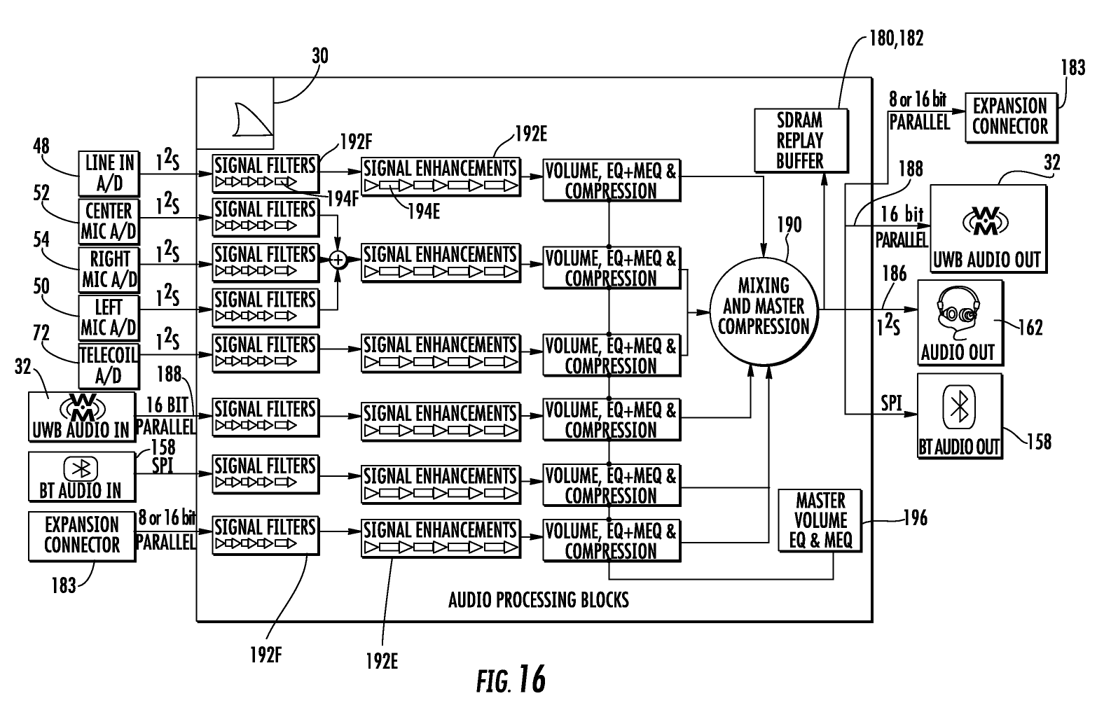

Turning now to audio output, as an alternative output to the hearing aid 12, the DSP device includes a conventional stereo audio out jack generally indicated at 162 (FIG. 15), which can be connected to any of a plurality of conventional hearing devices, such as stereo headphones 164 (FIG. 12) or stereo ear buds 166 (FIG. 13). The stereo output jack configuration 162 includes a conventional digital to analog (D/A) converter 168, an amplifier 170, an output surge protector 172 and a stereo jack connector 174.

As another alternative to the hearing aid 12, audio output can also be channeled through the Bluetooth® transceiver 158 to a conventional Bluetooth® headset 176 (FIG. 14).

We will turn to a more detailed discussion of the operation of the programmable DSP device 14 and how incoming audio streams are processed. There are several aspects to how the incoming audio streams are processed. As explained hereinabove, prior art hearing aids include a DSP, but because of size and power constraints, the DSP's are typically low power devices and are limited in functionality to single processing algorithm. In many cases, these low-power DSP's are customized ASIC chips, which are fixed hardware designs that cannot be altered, other than to change selected operating parameters.

The high-power DSP 30 of the present handheld DSP device 14 is a microcontroller based (software-based) device that is user programmable to accept different processing algorithms for “enhancing” audio signals received from the hearing aid, as well as other input sources, and gives the user control over selection of incoming sources and selective processing of audio signals.

“Processing” is generally defined as performing any function on the audio signal, including, but not limited to multiplexing, demultiplexing, “enhancing”, “filtering”, mixing, volume adjustment, equalization, compression, etc.

“Audio signal enhancement” involves the processing of audio signal to improve one or more perceptual aspects of the audio signals for human listening. These perceptual aspects include improving or increasing signal to noise ratio, intelligibility, degree of listener fatigue, etc. Techniques for audio signal processing or enhancement are generally divided into “filtering” and “enhancement”, although filtering is considered to be a subset of enhancement, “Enhancing” is generally defined as applying an algorithm to restore, emphasize or correct desired characteristics of the audio signal. In other words, an enhancement algorithm modifies desirable existing characteristics of the audio signal. “Filtering” is generally defined as applying an algorithm to an audio signal to improve sound quality by evaluating, detecting, and removing unwanted characteristics of the audio signal. In other words, a filtering algorithm generally removes something from the signal. The importance of the distinction of these two types of processing algorithms will only become apparent in the context of the order of application of the algorithms as further explanation of the system unfolds.

In the context of being user programmable, the handheld DSP device 14 includes built-in Flash memory 178 for storing the operating system of the device 14 as well as built-in SD Ram 180 for data storage (preferably at least 64 Megabytes) which can be used to store customization settings and plug-in processing algorithms. Further, the handheld DSP device 14 includes a memory card slot 182, preferably an SD memory card or mini-SD memory card, to receive an optional memory card holding up to an additional 2 gigabytes of data. Still in the context of being user programmable, the handheld DSP device 14 includes an expansion connector 183 and also a separate USB interface 184 for communication with a personal computer to download processing algorithms. The system further includes a host software package that will be installed onto a computer system and allow the user to communicate with and transfer data to and from the various memory locations 178, 180, 182 within the handheld DSP device 14. Communication and data transfer to and from the memory locations 178, 180, 182 and with other electronic devices is accomplished using any of the available communication paths, including wired paths, such as the USB interface 184, or wireless paths , such as the Bluetooth® link, and the UWB link etc.

Referring now to FIG. 15, a schematic block diagram of signal routing from the various inputs is illustrated. As can be seen, all of the wired inputs, i.e. the stereo audio input 48, wired microphones 50, 52, 54 and the telecoil sensor 72 are collected and multiplexed on a first communication bus 186 (I²S), and fed as a single data stream to the DSP 30. The I²S communication bus is illustrated as a representative example of a communication bus and is not intended to limit the scope of the invention. While only a single I²S communication bus 186 is shown in the drawings, it is to be understood that the device may further include additional I²S communication buses as well as other communication buses of mixed communication protocols, such as SPI, as needed to handle incoming and outgoing data.

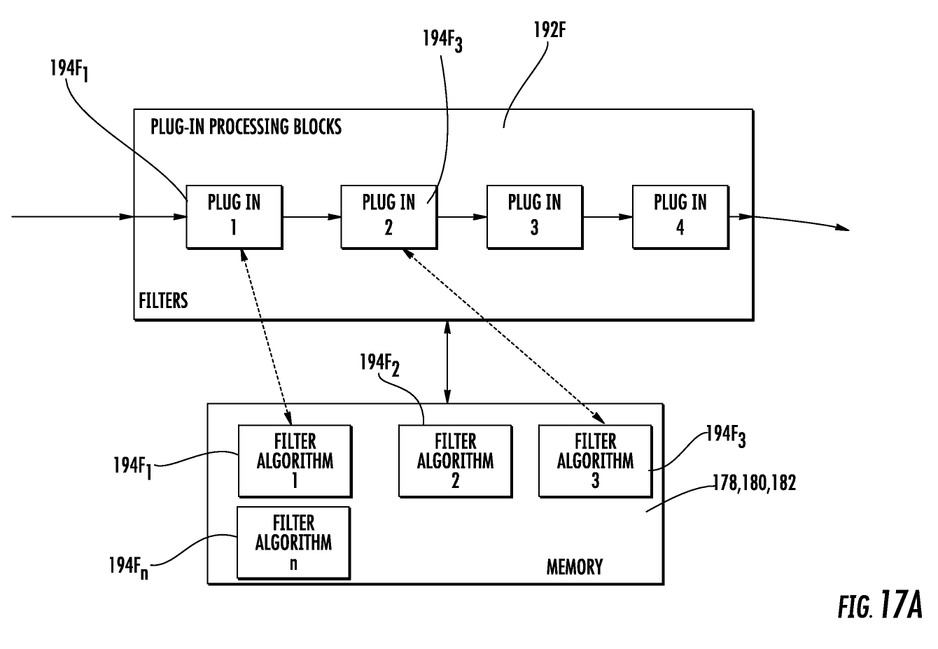

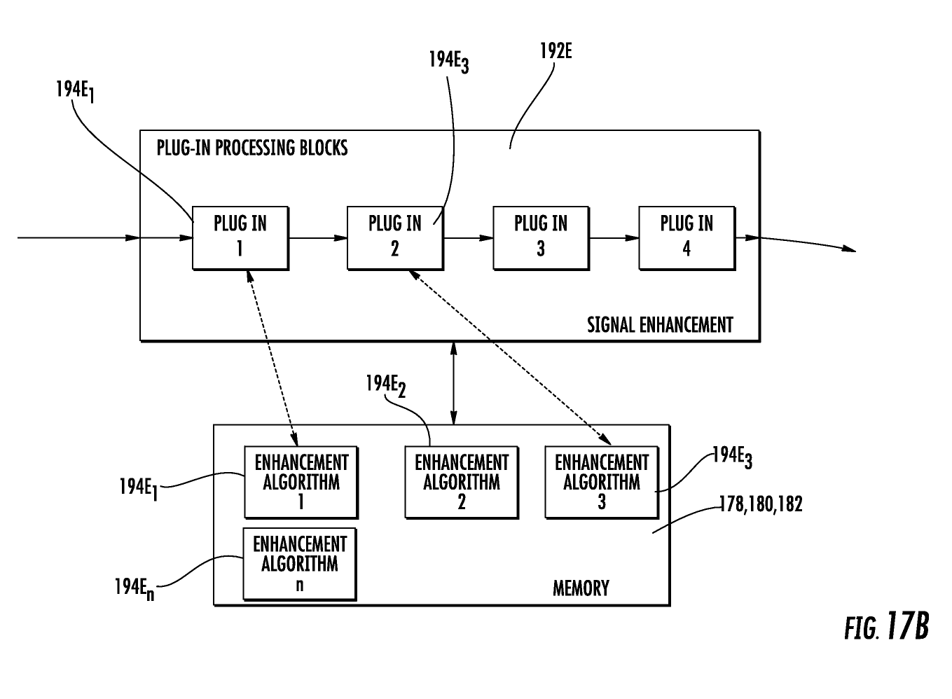

As will be described further hereinbelow, the DSP 30 has the ability to demultiplex the data stream and then separately process each of the types of input. Still referring to FIG. 15, the wireless transceiver inputs 32, 158 (UWB and Bluetooth®) are collected and multiplexed on a second communication bus 188 (16 bit parallel). The separate USB interface 184 is also multiplexed on the same communication bus 188 as the wireless transceivers 32, 158. As briefly explained hereinabove, the DSP 30 of the handheld DSP device 14 is user programmable and customizable to provide the user with control over the selection of input signals and the processing of the selected input signals. Referring to FIGS. 16 and 17, there are illustrated conceptual flow diagrams of signal processing in accordance with the present invention. In FIG. 16, it can be seen that each of the demultiplexed signal inputs 32, 48, 50, 52, 54, 72, 158, 183 can be processed with different signal filter algorithms and signal enhancement algorithms. All of the signal outputs are then combined (mixed) in a mixer 190 and routed to all of the communication buses. Output destined for wired output device 162 is routed through the I²S communication bus 186 to the stereo out jack 174. Output destined for the wireless hearing aid 12, or wireless Bluetooth® headset 176 is routed through the second communication bus 188 or alternate SPI bus.

The software system of the handheld DSP device 14 is based on a plug-in module platform where the operating software has the ability to access and process data streams according to different user-selected plug-ins. The concept of plug-in software modules is known in other arts, for example, with internet browser software (plug-in modules to enable file and image viewing) and image processing software (plug-in modules to enable different image filtering techniques). Processing blocks, generally indicated at 192, are defined within the plug-in software platform that will allow the user to select and apply pre-defined processing modules, generally indicated at 194, to a selected data stream. Plug-in processing modules 194 are stored in available memory 178, 180, 182 and are made available as selections within a basic drop-down menu interface that will prompt the user to select particular plug-in processing modules for processing of audio signals routed through different input sources. For purposes of this disclosure, the Applicant defines a processing module 194 as a plug-in module including a “processing algorithm” which is to be applied to the audio signal. The term “processing algorithm” is intended to include both filtering algorithms and enhancement algorithms.

Within the plug-in software system, the basic structure of all of the processing modules 194 is generally similar in overall programming, i.e. each module is capable of being plugged into the processing block of the software platform to be applied to the audio stream and process the audio stream. The difference between the individual processing modules 194 lies in the particular algorithm contained therein and how that algorithm affects the audio stream. As indicated above, we define filter modules 194F and enhancement modules 194E. As used herein, a “filter module” 194F is intended to mean a module that contains an algorithm that is classified as a filtering algorithm. As used herein an “enhancement module” 194E is intended to mean a module 194 that contains an algorithm that is classified as an enhancing algorithm.

Now turning to the motivation for separating “filtering algorithms” from “enhancement algorithms”, it is recognized by the Applicant that it is preferable to apply filters to the audio signal to improve the signal to noise ratio prior to applying enhancements. Accordingly, to simplify the user interface, and improve functionality of a device that would be programmed by those with only limited knowledge of audio processing, the Applicant's separated the selection and application of filter algorithms and enhancement algorithms into two sequential processing blocks. Referring to FIG. 15, within each data stream, there are defined two successive processing blocks 192, namely a first processing block 192F for selectively applying filter modules 194F, and a second processing 192E for selectively applying enhancement modules 194E.

During a setup mode, the user will scroll through a drop down menu of available input sources to select a particular input source, or multiple input sources. For example, if the user were sitting at home watching television with a family member, the user may select to have two inputs, namely a wireless audio adapter input 76 to receive audio signals directly from the television, as well as a wireless microphone input 78 to hear the other person seated in the room. All other inputs may be unselected so that the user is not distracted by unwanted noise. Alternately, if the user were at a restaurant with several companions, the user may have several wireless microphones 78 that are paired with the handheld DSP device 14 and then selected as input sources to facilitate conversation at the table. All other input sources could be unselected. Input source selection is thus easily configured and changed on the fly for different environments and hearing situations. Commonly used configurations will be stored as profiles within the user set-up so that the user can quickly change from environment to environment without having the reconfigure the system each time.

For each incoming audio source, the user can customize filtering and enhancement of each incoming audio source according the users' own hearing deficits and/or hearing preferences (See FIGS. 16, 17A and 17B). Similar to the selection of available incoming audio sources, for each incoming audio source, the user will selectively apply desired filter modules 194F and signal enhancement modules 194E to improve the sound quality. In this regard, a plurality of software-based digital signal filter modules 194F is stored in memory for selective application to an incoming audio source. For example, the user may have several different filter modules 194F that have been developed for different environmental conditions, i.e. noise reduction, feedback reduction, directional microphone, etc. . . . The user may select no filters, one filter or may select to apply multiple filters. For example, the stereo audio line-in may be used to receive input from a digital music player (MP3). This type of incoming audio stream is generally a clean, high-quality digital signal with little distortion or background noise. Therefore, this incoming signal may not require any signal filtering at all. Accordingly, the user may elect not to apply any of the available signal filters. However, if the desired incoming audio source is a wireless microphone in a restaurant, the user may want to apply a noise reduction filter.

In FIGS. 16 and 17A, there are shown filter processing blocks 192F which illustrate the ability to apply plug-in filter modules 194F. The user can thus apply different filter modules 194F to each of the different incoming audio sources. Where multiple filter modules 194F are selected, the filter modules 194F are applied in series, one after the other. In some cases, the order of application of the filter modules 194F may make a significant difference in the sound quality. The user thus has the ability to experiment with different filter modules 194F and the order of application, and may, as a result, find particular combinations of filter modules 194F that work well for their particular hearing deficit.

As indicated above, the user may connect the handheld DSP device 14 to the user's computer, and using the device interface software, download into memory a plurality of different signal filter modules 194F available within the user software. It is further contemplated that the interface software will have the ability to connect to the internet and access an online database(s) of filters modules 194F that can be downloaded. In the future, as new filter modules 194F are developed, they can be made available for download and can be loaded onto the handheld DSP device 14.

For each incoming audio source, the user can further customize enhancement of each incoming audio source according the user's own hearing deficits and/or hearing preferences. Similar to the selection of available incoming audio sources and filter modules 19F, for each incoming audio source, the user will selectively apply desired enhancement modules 194E to improve the sound quality each of different audio source. In this regard, a plurality of software-based enhancement modules 194E is stored in memory for selective application to an incoming audio source. Referring to FIGS. 16 and 17B, for example, the user may have several different enhancement modules 194E that have been developed for different environmental conditions, i.e. volume control, multi-band equalization, balance, multiple sound source mixing, multiple microphone beam forming, echo reduction, compression decompression, signal recognition, error correction, etc. It is a feature of the present invention to be able to selectively apply different enhancement modules 194E to different incoming audio streams. Where multiple enhancement modules 194E are selected, the enhancements are applied in series, one after the other. In some cases, the order of application of the enhancements modules 194E may make a significant different to the sound quality. The user thus has the ability to experiment with different enhancements 194E and the order of application, and may, as a result, find particular combinations of enhancements 194 that work well for their particular hearing deficit. The user thus has the ability to self-test and self-adjust the assistive listening system and customize the system for his/her own particular needs.

Again, as indicated above, the user may connect the handheld DSP device 14 to the user's computer, and using the device interface software, download into memory 178, 180, 182 a plurality of different signal enhancement algorithms 194E available within the user software. It is further contemplated that the interface software will have the ability to connect to the internet and access an online database(s) of enhancement algorithms 194E that can be downloaded. In the future, as new enhancement algorithms 194E are developed, they can be made available for download and can be loaded onto the handheld DSP device 14.

Turing back to FIG. 16, a feature of the invention is the ability to make global adjustments to each of the audio streams after filtering and enhancement. As can be seen, the system is configured to apply a master volume and equalization setting and apply a master dynamic range compression (automatic gain control (AGC)) 196 to the multiple audio streams prior to mixing the audio streams together. Separate audio signals may have significantly different volume levels and an across the board volume adjustment at the end of the process may not enhance sound intelligibility, but rather degrade sound intelligibility. It is believed that applying a master volume and equalization adjustment 196 prior to mixing provides for a more evenly enhanced sound and better overall sound intelligibility, as well as reducing processing requirements.

After application of the master volume and equalization adjustments 196, the audio signal streams are mixed 190 into a single audio stream for output. After mixing, the single output stream is compressed (AGC) for final output to the user, whether through the wireless hearing aid link, wireless Bluetooth® link, or wired output.

Referring to FIGS. 15 and 16, another aspect of the invention is that the system is configured to buffer and store in memory a predetermined portion of the audio output for an instant replay feature. The buffered output is stored in available memory 180 on board the handheld DSP device 14 or on a removable storage media (SD card) 182. Preferably, the system continuously buffers the previous 30 seconds of audio output for selective replay by the user, although the system also preferably provides for the user to select the time segment of the replay buffer, i.e. 15 seconds, 20 seconds, 30 seconds, etc. Accordingly, if the user cannot decipher a particular part of the previously heard output, the user can press an input key 38, (such as a dedicated replay key) which triggers the system to temporarily switch the output to replay of the buffered audio. The user can then better distinguish the audio the second time. As a further enhancement to the replay feature, the system is further configured to convert the replayed audio into text format (for speech) and to display the converted speech on the LCD screen 36 of the handheld DSP device 14. Speech to text conversion programs are well known in the art, and the operating system of the handheld DSP 14 is configured with a speech to text sub-routine that is employed during the replay function. It is preferred that the replay audio is buffered after application of all of filters 194 and enhancements 194 and after mixing 190 to the single audio output stream. The enhanced sounds, particularly voices may thus be better distinguished by both the user and by the speech to text program. As a further alternative, the system can be configured to employ the speech to text conversion sub-routine as a personal close-captioning service. In this regard, the speech to text conversion program is constantly running and will display converted text to the user at all times.

It is a further aspect of the system 10 that each of the audio signals can be separately buffered and stored in available memory. In this regard, the system is capable of replaying the audio from only signal source. For example, if the user had an audio signal from a television source and another audio signal from another person, the user could selectively replay the signal originating from the other person so as to be better able to distinguish the spoken words of the individual rather than having the audio mixed with the television source. Likewise, only that isolated audio signal could be converted to text so that the user was able to read the text of the conversation without having the distraction of the television dialogue interjected with the conversation.

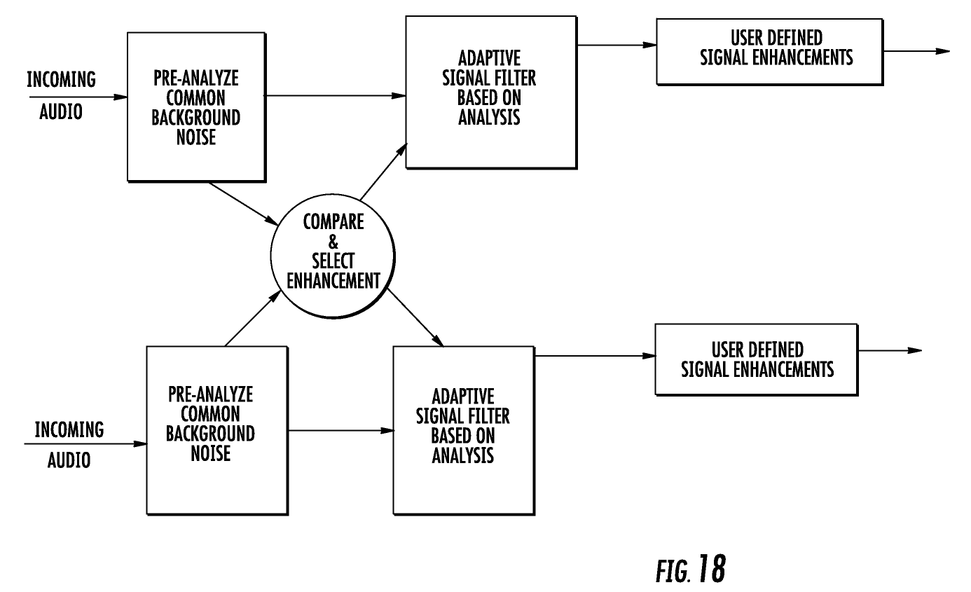

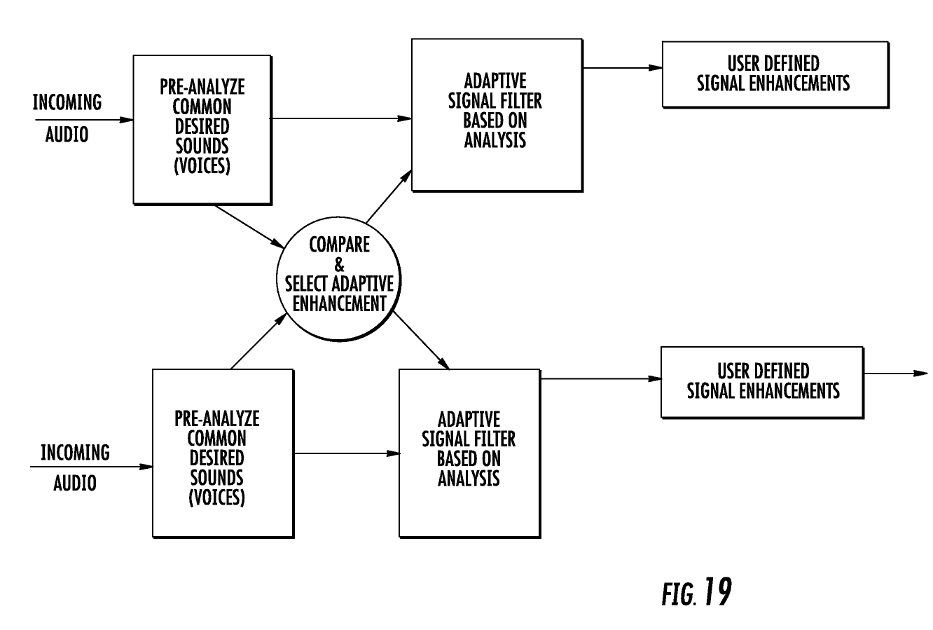

Referring to FIG. 18, another feature of the invention related to the processing of multiple incoming audio signals, is the ability of the DSP 30 to pre-analyze parallel incoming audio signals before enhancing the sound. One implementation is to pre-analyze parallel incoming audio signals for common background noises and then adaptively process the incoming audio signals to remove or reduce the common background noises. More specifically, the DSP 30 analyzes each of the incoming audio signals and looks for common background noise in each of the audio signals. The DSP 30 can then selectively apply an adaptive filter module or other module that will filter out the common background noise in each of the channels thus improving and clarifying the audio signal in both audio streams. The increased processing power of the DSP 30 in the handheld device 14 provides the ability to conduct these extra analyzing functions without degrading the overall performance of the device.

In the same context, referring to FIG. 19, another implementation is to pre-analyze parallel incoming audio signals for common desirable sounds. For example, the system could be programmed to analyze the incoming audio signals for common sound profiles and frequency ranges of peoples' voices. After analyzing for common desirable sounds, the system would then adaptively filter or process the incoming audio signals to remove all other background noise to emphasize the desired voices and thus enhance intelligibility of the voices.

It can therefore be seen that the instant invention provides an assistive listening system 10 including both a functional at-ear hearing aid 12, or pair of hearing aids 12, and a separate handheld digital signal processing device 14 that supplements the functional signal processing of the hearing aid 12, and further provides a control system 46 on board the hearing aid(s) that controls routing of incoming audio signals according to wireless transmission status and power status. The system 10 still further provides a handheld digital signal processing device 30 that can accept audio signal from a plurality of different sources and that includes a versatile plug-in software platform that provides for selective application of different signal filters and sound enhancement algorithms to selected sound sources.

While there is shown and described herein certain specific structure embodying the invention, it will be manifest to those skilled in the art that various modifications and rearrangements of the parts may be made without departing from the spirit and scope of the underlying inventive concept and that the same is not limited to the particular forms herein shown and described except insofar as indicated by the scope of the appended claims. For example, although a Blackfin™ digital signal processor is identified and described as the preferred device for processing, it is also contemplated that other devices, such as ASIC's, FPGA's, RISC processors, CISC processors, etc. could also be used to perform at least some of the calculations required herein. Additionally, although the invention focuses on the use of the present system for the hearing impaired, it is contemplated that individuals with normal hearing could also benefit from the present system. In this regard, there are potential applications of the present system in military and law enforcement situations, as well as for the general population in situations where normal hearing is impeded by excessive environment noise.

What is claimed is:

1. A method of processing sound comprising the steps of:
receiving at a first input a first digital audio signal generated from a first audio source;
receiving at a second input a second digital audio signal generated from a second audio source;
processing said first digital audio signal according to a first signal processing algorithm;
processing said second digital audio signal according to a second signal processing algorithm;
adjusting a master volume and equalization of each of said processed first and second audio signals;
mixing said adjusted first and second processed audio signals; and
outputting said mixed first and second audio signals.

2. A method of processing sound comprising the steps of:
receiving at a first input a first digital audio signal generated from a first audio source;
receiving at a second input a second digital audio signal generated from a second audio source;
adjusting a master volume and equalization of each of said first and second audio signals;
mixing said adjusted first and second audio signals; and
outputting said mixed first and second audio signals.
